(19) United States
(12) Patent Application Publication
(10) Pub. No.: US 2014/0060908 A1
(43) Pub. Date: Mar. 6, 2014

(54) PRINTED CIRCUIT BOARD AND THE METHOD FOR MANUFACTURING THE SAME

(71) Applicants: Chung Sik Park, Seoul (KR); Duk Nam Kim, Seoul (KR); Jae Hyun Ahn, Seoul (KR)

(72) Inventors: Chung Sik Park, Seoul (KR); Duk Nam Kim, Seoul (KR); Jae Hyun Ahn, Seoul (KR)

(73) Assignee: LG INNOTEK CO., LTD., Seoul (KR)

(21) Appl. No.: 14/115,138

(22) PCT Filed: Apr. 26, 2012
(86) PCT No.: PCT/KR2012/003236

§ 371 Date: Nov. 4, 2013

(30) Foreign Application Priority Data
May 3, 2011 (KR) 10-2011-0042157

(51) Int. Cl. H05K 3/38; H05K 1/02

(52) U.S. Cl. CPC H05K 3/388; H05K 1/0201
USPC 174/257; 174/262; 216/19

(57) ABSTRACT

A printed circuit board includes a first insulating layer, a second insulating layer on the first insulating layer, and at least one via formed through the first and second insulating layers in a layered structure. The via includes a first via layer formed through the first insulating layer, a second via layer formed on the first via layer while passing through the second insulating layer, and an adhesive layer between the first and second via layers. The first via layer has a section different from a section of the second via layer. The adhesive property between the copper layer and the insulating layer is improved. The vias used to connect interlayer circuits to each other are formed between a plurality of insulating layers through an etching process instead of a laser process or a polishing process, thereby improving the process ability and reducing the manufacturing cost.

### TECHNICAL FIELD

The present invention relates to a printed circuit board and a method for manufacturing the same.

### BACKGROUND ART

Circuit boards refer to electrical insulating substrates printed with circuit patterns, and are used to mount electronic components thereon.

Recently, among the circuit boards, a thin multi-layer circuit board has been suggested. To manufacture the thin multi-layer circuit board, various attempts of forming a thin support substrate to support the bending of an intermediate central layer during a process for the intermediate central layer have been suggested.

FIG. 1 is a sectional view showing a printed circuit board 10 according to the related art.

The printed circuit board 10 according to the related art includes multi-layer circuit patterns 4 and 5 formed between a plurality of multi-layer insulating layers 1, and is formed therein with vias 2 and 3 used to connect the circuit patterns 4 and 5 to each other.

In this case, the vias 2 and 3 are filled with conductive paste after a mechanical hole process has been performed, or formed through a plating process after a hole process has been performed through a laser drill scheme.

In this case, the scheme of forming the via 2 by using the conductive paste is employed when the plating scheme may not be employed due to the great size of the via 2. However, the via 2 formed by the conductive paste represents great electrical resistance, so that the transmission signal may have noise. Accordingly, the reliability may be degraded.

Meanwhile, in the case of the via 3 formed through a laser drilling scheme, a hole process is required with respect to each insulating layer 1, so that the economical problem is caused.

### DISCLOSURE OF INVENTION

### Technical Problem

The embodiment provides a printed circuit board having a novel structure and a method for manufacturing the same.

The embodiment provides a printed circuit board and a method for manufacturing the same, in which vias are formed through a simple process.

### Solution to Problem

According to the embodiment, there is provided a printed circuit board including a first insulating layer, a second insulating layer on the first insulating layer, and at least one via formed through the first and second insulating layers and having a layer structure. The via includes a first via layer formed through the first insulating layer, a second via layer formed on the first via layer while passing through the second insulating layer, and an adhesive layer between the first and second via layers. The first via layer has a section different from a section of the second via layer.

According to the embodiment, there is provided a method for manufacturing a printed circuit board. The method includes forming a via groove in a via region of each of a plurality of bulk metallic layers to form a via layer, filling a first insulating layer in the via groove of one bulk metallic layer, forming an adhesive layer on a plurality of via grooves of the one bulk metallic layer, arranging the via layer of another bulk metallic layer on the adhesive layer and bonding the bulk metallic layers to each other while filling a second insulating layer into the via groove, and etching the bulk metallic layers to expose the first and second insulating layers.

### Advantageous Effects of Invention

As described above, according to the present invention, the adhesive property between the copper layer and the insulating layer is improved, and bulk copper is used, so that the heat radiation property can be improved.

In addition, the vias used to connect interlayer circuits to each other are formed between a plurality of insulating layers through an etching process instead of a laser process or a polishing process, so that the process ability can be improved, and the manufacturing cost can be reduced.

### BRIEF DESCRIPTION OF DRAWINGS

FIG. 1 is a sectional view showing a printed circuit board according to the related art;

FIG. 2 is a sectional view showing a device chip package employing a printed circuit board according to the embodiment of the present invention;

FIGS. 3 to 16 are sectional views showing a method for manufacturing the printed circuit board of FIGS. 2; and

FIG. 17 is a sectional view showing a device chip package employing the printed circuit board of FIG. 2.

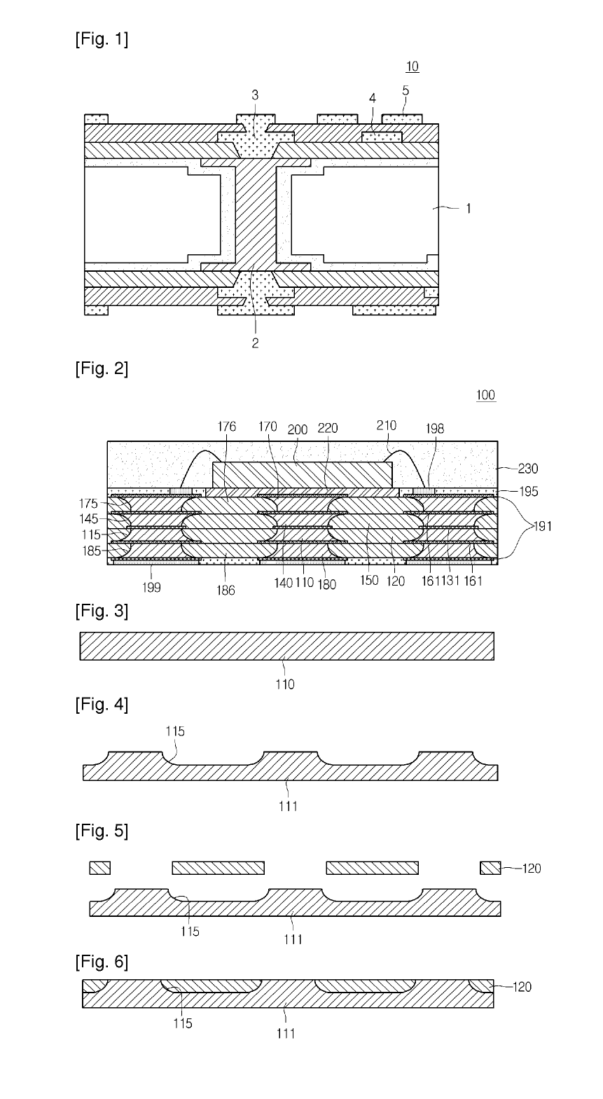

### BEST MODE FOR CARRYING OUT THE INVENTION

Hereinafter, embodiments will be described in detail with reference to accompanying drawings so that those skilled in the art can easily work with the embodiments. However, the embodiments may have various modifications.

However, the present invention can be realized as various modifications, and is not limited to the embodiments.

In the following description, when a predetermined part “includes” a predetermined component, the predetermined part does not exclude other components, but may further include other components if there is a specific opposite description.

The thickness and size of each layer shown in the drawings may be exaggerated, omitted or schematically drawn for the purpose of convenience or clarity. In addition, the size of elements does not utterly reflect an actual size. The same reference numbers will be assigned the same elements throughout the drawings.

In the description of the embodiments, it will be understood that, when a layer (or film), a region, or a plate is referred to as being “on” or “under” another layer (or film), another region, or another plate, it can be “directly” or “indirectly” on the other layer (or film), region, plate, or one or more intervening layers may also be present. Such a position of the layer has been described with reference to the drawings.

The present invention provides a printed circuit board which does not employ a laser drilling scheme when forming a via hole.

Hereinafter, a heat radiating circuit substrate according to the embodiment of the present invention will be described with reference to FIGS. 2 to 16.

FIG. 2 is a sectional view showing a printed circuit board according to the embodiment of the present invention and a device chip package 100 employing the printed circuit board.

Referring to FIG. 2, the device chip package 100 according to the present invention includes the printed circuit board and a device chip 200 mounted on the printed circuit board.

The printed circuit board includes a plurality of insulating layers 120, 150, 176, and 186, a plurality of vias formed through the insulating layers 120, 150, 176, and 186, and a coverlay 195 to cover the vias.

The insulating layers 120, 150, 176, and 186 include the first insulating layer 120, the second insulating layer 150 formed on the first insulating layer 120, and third and fourth insulating layers 176 and 186 formed on the first insulating layer 176 and under the fourth insulating layer 186, respectively.

The first to fourth insulating layers 120, 150, 176, and 186 may include epoxy insulating resin representing low thermal conductivity (about 0.2 W/mK to about 0.4 W/mk). Alternatively, the first to fourth insulating layers 120, 150, 176, and 186 may include poly imide resin representing high thermal conductivity. In addition, the first to fourth insulating layers 120, 150, 176, and 186 may include the same material. Alternatively, the first to fourth insulating layers 120, 150, 176, and 186 may include materials different from each other.

In addition, the first to fourth insulating layers 120, 150, 176, and 186 are formed by filling adjacent vias with a predetermined material, and have sectional shapes varied according to the shapes of the vias.

The vias may be spaced apart from each other, and may include through vias formed by perforating from the top surface of the printed circuit board to the bottom surface of the printed circuit board.

Each via has a layer structure including a plurality of layers.

Each via includes a first via layer formed by perforating the first insulating layer 120, a second via layer 140 formed through the second insulating layer 150 and aligned with the first via layer 110, and third and fourth via layers 170 and 180 formed on the first via layer 110 and under the second via layer 140, respectively, by perforating the third and fourth insulating layers 176 and 186, respectively.

In this case, although the present invention has been described in that the printed circuit board is limited to a multi-layer structure having four insulating layers 120, 150, 176, and 186, so that the vias are formed in a four layer-structure, the vias may be designed as many as the number of the insulating layers 120, 150, 176, and 186. In addition, the vias has the layer structure having layers, the number of which is fewer than the number of the insulating layers 120, 150, 176, and 186, so that the shape of the filled via can be represented instead of the shape of the through via.

Hereinafter, the via having a four-layer structure will be described.

The first via layer 110 is formed at the central region of the printed circuit board, and has a sectional shape gradually enlarged toward the lower portion thereof.

The second via layer 140 extends from the top surface of the first via layer 110, and has a sectional shape gradually enlarged toward the upper portion thereof.

The third via layer 170 may be formed on the second via layer 140, and may have the same shape as that of the second via layer 140. The fourth via layer 180 may be formed under the first via layer 110, and may have the same shape as that of the first via layer 110.

In other words, the plural layer structure may have a symmetric structure about the central region.

The first to fourth via layers 110, 140, 170, and 180 may include the same material.

Preferably, the first to fourth via layers 110, 140, 170, and 180 may include copper which is a conductive material representing superior heat radiation property.

Meanwhile, a plurality of adhesive layers 131, 161, and 191 may be formed between the via layers.

The adhesive layers 131, 161, and 191 include the first adhesive layer 131 formed between the first and second via layers 110 and 140, the second adhesive layers 161 formed between the second and third via layers 140 and 170 and between the first and fourth via layers 110 and 180, respectively, and the third adhesive layers 191 formed on the surface of the third via layer 170, which is exposed through the top surface of the printed circuit board, and formed on the surface of the fourth via layer 180, which is exposed through the bottom surface of the printed circuit board.

The adhesive layers 131, 161, and 191 may include the same material, and used to bond a plurality of via layers formed through different processes to each other. The adhesive layers 131, 161, and 191 may include the same material as that of the via layers.

In other words, the adhesive layers 131, 161, and 191 may include the alloy containing copper.

The printed circuit board is provided on the top and bottom surfaces thereof with coverlays 195, and portions of vias are exposed from the coverlay 195 to form pads 198 and 199.

The pads 198 and 199 may include the alloy containing metal such as silver, gold, nickel or palladium, and include the inner lead 198 formed on a surface having a chip to be formed thereon and the outer lead 199 formed on a rear surface provided in opposition to the surface having the chip to be formed thereon.

A solder paste 220 is coated on the exposed top surface of the via, and the device chip 200 is mounted on the solder paste 220.

The device chip 200 may include a semiconductor chip, a light emitting diode chip, and other driving chips. In addition, the device chip 200 is electrically connected to the inner lead 198 through a wire 210.

The device chip 200 is molded by a resin 230 so that the device chip 200 can be protected from the outside.

Hereinafter, a method for manufacturing the printed circuit board of FIG. 2 will be described with reference to FIGS. 3 to 16.

First, as shown in FIG. 3, the first bulk metallic plate 111 is prepared.

The first bulk metallic plate 111 may include a copper plate having a thickness greater than that of each via layer.

Next, a first insulating groove 115 is formed by etching a space between the vias except for the region for the formation of the via as shown in FIG. 4.

The first insulating groove 115 may be formed by performing a wet etching scheme after a resist pattern is formed on the copper plate 111, and may have a curved section.

Therefore, a protrusion constituting the first via layer 110 is formed between the first insulating grooves 115.

Next, as shown in FIG. 6, after forming a hole corresponding to the first via layer 110 in the first insulating layer 120, the first insulating layer 120 is pressed against the first metallic plate 111, so that the first insulating layer 120 is filled in the first insulating groove 115 of the first metallic plate 111.

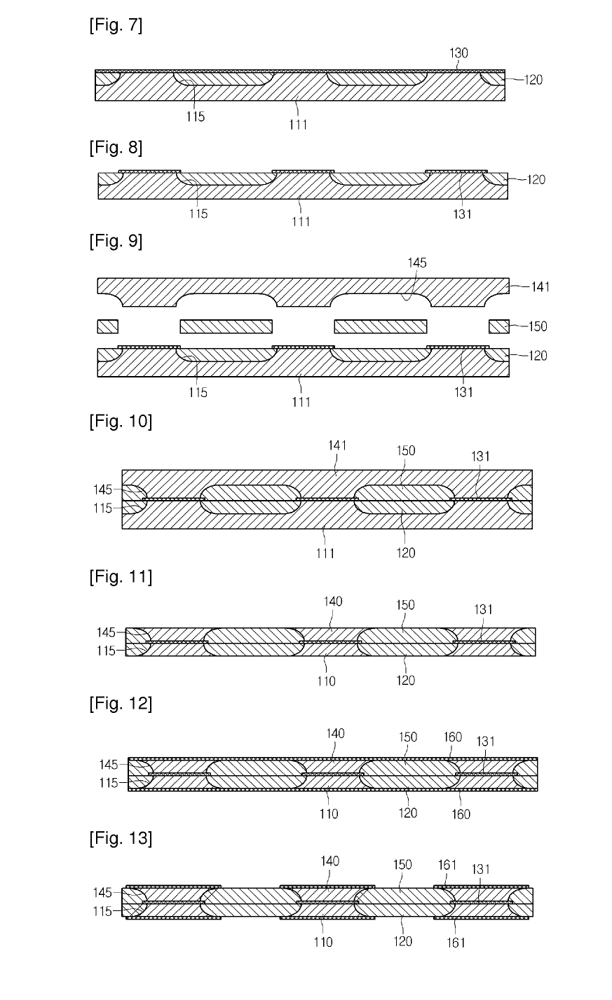

Next, as shown in FIG. 7, the first metallic layer 130 is formed on the first via layer 110 and the first insulating layer 120.

The first metallic layer 130 may be formed by depositing copper through an aerosol deposition scheme. In other words, mixture of the copper and gas is aerosolized and sprayed on the first via layer 110 and the first insulating layer 120 through a nozzle, thereby forming the first metallic layer 130.

When the aerosol deposition is performed in order to form he metallic layer 130, deposition is achieved at a room temperature instead of a high temperature.

Next, as shown in FIG. 8, the first metallic layer 130 is etched except for the upper portion of the first via layer 110, thereby forming the first adhesive layer 131 of FIG. 2.

In this case, the first metallic layer 130 may be etched through a wet etching process after the resist pattern has been formed. In this case, the first adhesive layer 131 has a surface extending to the upper portion of the first insulating layer 120 so that the first adhesive layer 131 has a surface wider than the top surface of the first via layer 110.

Next, as shown in FIG. 9, after forming a second insulating groove 145 in a second metallic plate 141 by repeating the processes of FIGS. 2 to 4, the second metallic plate 141 is arranged in such a manner that the second insulating groove 145 faces the first insulating layer 115. Then, the second insulating layer 150 is provided corresponding to the second insulating groove 145, and heat and pressure are applied to the first and second metallic plates 111 and 141, thereby completing the shape of FIG. 10.

Subsequently, as shown in FIG. 11, both surfaces of the first and second metallic plates 111 and 141 are etched until the first and second insulating layers 120 and 150 are exposed, thereby forming the first and second via layers 110 and 140 of FIG. 2.

Next, as shown in FIG. 12, the second metallic layers 160 are formed on the first and second via layers 110 and 140 and the exposed first and second insulating layers 120 and 150.

Each second metallic layer 160 is formed by using a copper layer through an aerosol deposition scheme as shown in FIG. 7, and portions of the second metallic layers 160 are etched to form the second adhesive layers 161 on the first and second via layers 110 and 140 as shown in FIG. 13.

The second adhesive layer 161 has an area wider than that of the first adhesive layer 131 due to the shapes of the first and second via layers 110 and 140.

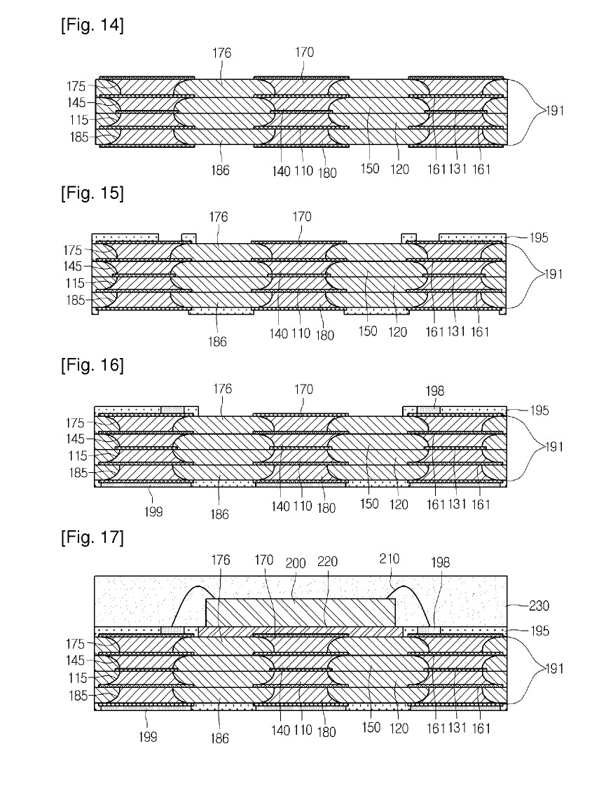

Subsequently, a multi-layer structure of FIG. 14 is formed by repeating the processes of FIGS. 3 to 13.

In the multi-layer structure of FIG. 14, the third via layer 170 is formed on the second via layer 140, the fourth via layer 180 is formed under the first via layer 110, and the third adhesive layers 191 are formed on the exposed surface of the first and fourth via layers 110 and 180.

The third adhesive layers 191 may have the same shape as that of the second adhesive layers 161, and have areas extending to the upper portions of the third and fourth insulating layers 176 and 186.

Subsequently, areas in which the inner lead 198, the outer lead 199, and the device chip 200 are formed are exposed and the coverlay 195 is formed.

The coverlay 195 may include solder resist or a dry film.

Next, the inner lead 198 and the outer lead 199 are formed by plating the exposed surfaces of the coverlay 195. The inner lead 198 and the outer lead 199 may include the alloy containing metal such as silver, gold, nickel, or palladium, and may be subject to plating, so that the inner lead 198 and the outer lead 199 may have a multi-layer structure.

As shown in FIG. 16, if the pads of the inner lead 198 and the outer lead 199 are formed, the printed circuit board is completed.

As shown in FIG. 17, after coating the solder paste 220 on the mounting region of the device chip 200 of the printed circuit board of FIG. 16, the device chip 200 is mounted, and the device chip 200 is electrically conducted with the inner lead 198 through the wire 210, thereby completing the package 100 of the device chip 200.

As described above, when forming a multi-layer via in the printed circuit board having a multi-layer insulating layer, the via is formed through the etching process, so that the cost can be reduced. In addition, the adhesive layer is formed between via layers, so that an adhesive strength and a signal characteristic can be ensured.

Although exemplary embodiments of the present invention have been described for illustrative purposes, those skilled in the art will appreciate that various modifications, additions and substitutions are possible, without departing from the scope and spirit of the invention as disclosed in the accompanying claims.

1. A printed circuit board comprising:
a first insulating layer;
a second insulating layer formed on the first insulating layer; and
at least one via formed through the first and second insulating layers and formed in a layered structure,
wherein the via comprises:
a first via layer formed through the first insulating layer;
a second via layer formed on the first via layer while passing through the second insulating layer; and
an adhesive layer formed between the first and second via layers,
wherein the first via layer has a first section a lower width of the first section being smaller than an upper width of the first section, and
wherein the second via layer has a second section in contact with the first section of the first via layer, a lower width of the second section being larger than an upper width of the second section.

2. The printed circuit board of claim 1, wherein the section of the first via layer is symmetrical to the section of the second via layer about the adhesive layer.

3. The printed circuit board of claim 2, wherein the sections of the first and second via layers are enlarged as the first and second via layers are away from the adhesive layer.

4. The printed circuit board of claim 3, wherein lateral sides of the first and second via layers are recessed in a concave shape.

5. The printed circuit board of claim 1, wherein the first via layer includes a material equal to a material of the second via layer.

6. The printed circuit board of claim 1, wherein the adhesive layer includes a material equal to a material of the first via layer.

7. The printed circuit board of claim 1, wherein the adhesive layer and the first and second via layers include an alloy including copper.

8. The printed circuit board of claim 1, wherein the adhesive layer is formed by aerosol deposition.

9. The printed circuit board of claim 1, further comprising third and fourth via layers extending to from an upper portion of the first via layer and a lower portion of the second via layer, respectively.

10. The printed circuit board of claim 9, further comprising additional adhesive layers among the first to fourth via layers.

11. The printed circuit board of claim 1, wherein the adhesive layer includes a region extending to the first and second insulating layers.

12. A method for manufacturing a printed circuit board, the method comprising:
forming a via groove in each of a plurality of bulk metallic layers to form a via layer;
filling a first insulating layer in the via groove of one of the plurality of bulk metallic layers;
forming an adhesive layer on the via groove of the one of the plurality of bulk metallic layers;
arranging the via layer of another of the bulk metallic layers on the adhesive layer and bonding the bulk metallic layers to each other while filling a second insulating layer into the via groove of the other of the bulk metallic layers and facing the first insulating layer and the second insulating layer each other; and
etching the bulk metallic layers to expose the first insulating layer and the second insulating layer.

13. The method of claim 12, wherein
the via groove is formed by wet-etching a region except the via layer.

14. The method of claim 12, wherein the forming of the adhesive layer comprises:
depositing metal on an entire surface of the bulk metallic layer through an aerosol deposition scheme; and
forming the adhesive layer by wet-etching the deposited metal.

15. The method of claim 14, wherein the adhesive layer extends to a portion of the first and second insulating layers.
